(19) United States
(12) Patent Application Publication
(10) Pub. No.: US 2024/0371808 A1
(43) Pub. Date: Nov. 7, 2024

(54) SEMICONDUCTOR PACKAGE

(71) Applicant: Samsung Electronics Co., Ltd., Suwon-si (KR)

(72) Inventor: Won-Young KIM, Suwon-si (KR)

(73) Assignee: Samsung Electronics Co., Ltd., Suwon-si (KR)

(21) Appl. No.: 18/507,617

(22) Filed: Nov. 13, 2023

(30) Foreign Application Priority Data
May 4, 2023 (KR) 10-2023-0058694

(51) Int. Cl. H01L 23/00; H01L 23/48; H01L 25/065

(52) U.S. Cl. CPC H01L 24/06; H01L 23/481; H01L 24/08; H01L 24/16; H01L 24/32; H01L 24/73; H01L 25/0657; H01L 2224/06177; H01L 2224/06181; H01L 2224/08145; H01L 2224/16145; H01L 2224/16225; H01L 2224/32225; H01L 2224/73204

(57) ABSTRACT

A semiconductor structure may include an interposer die, a slave die, a plurality of first connection members and a plurality of second connection members. The interposer die may include a first surface and a second surface that is an opposite surface of the first surface. The slave die may include a third surface and a fourth surface that is an opposite surface of the third surface, and a plurality of through-silicon vias. The plurality of first connection members may be disposed on the first surface. The plurality of second connection members may electrically connect the second surface and the third surface.

### CROSS-REFERENCE TO RELATED APPLICATION

This application claims priority under 35 U.S.C. 119 to Korean Patent Application No. 10-2023-0058694 filed in the Korean Intellectual Property Office on May 4, 2023, the entirety of which is hereby incorporated by reference.

### BACKGROUND

### Field of the Invention

The present disclosure relates to semiconductor packages.

Description of the Related Art As the demand for miniaturization and weight reduction of electronic devices has increased in the semiconductor industry, semiconductor packages to be mounted on electronic devices have become increasingly miniaturized, lightweight, and thinned, while at the same time being implemented in high-speed, multifunctional, and high-integration density semiconductor packages. Therefore, the need for packaging technology capable of storing more data and transmitting data at a higher speed is increasing, and as such packaging technology including 3-dimensional stacked (3DS) semiconductor packages in which a plurality of chips are stacked in a single package is being developed.

A 3D stacked semiconductor package may include a master die and one or more slave dies stacked on the master die. The master die may be a buffer chip for controlling the one or more slave dies. In addition, the master die may perform a logical operation on data output from the one or more slave dies and output a result of the logical operation to communicate with the outside. The slave die may be a memory cell chip having DRAM cells. In addition, the slave die may communicate with the master die through internal circuitry and through-silicon vias (TSVs).

In a 3D stacked semiconductor package, defects such as failure of the master die or the slave die to satisfy specifications required for individual chips may occur.

When a defect occurs in a master die of a 3D stacked semiconductor package, since the master die and the substrate of the package each have input/output terminals or connectors (e.g., I/Os) having a same normal pitch, a single chip in which the I/Os of the master die and the I/Os of the substrate are connected may be manufactured to recycle (e.g., replace) the defective master die. However, if a defect occurs in a slave die of a 3D stacked semiconductor package, since the slave die has I/Os with fine pitch and the substrate has I/Os with normal pitch that may be greater than the fine pitch, direct connection between the slave die and the substrate is not possible, and the defective slave die of the 3D stacked semiconductor package cannot be replaced and has to be discarded.

Therefore, it is necessary to develop a new semiconductor package technology capable of recycling or replacing defective slave dies.

### SUMMARY

Embodiments of the inventive concepts provide a semiconductor package that forms an interposer designed to be capable of electrical connection to a slave die in consideration of constraints such as pitch, size, and design of the I/Os of the slave die, and may include a single chip where the slave die is disposed on the interposer or a multi-chip where a plurality of slave dies are disposed on the interposer. Embodiments of the inventive concepts provide a semiconductor structure which may include an interposer die including a first surface and a second surface opposite the first surface; a slave die including a third surface and a fourth surface opposite the third surface, the slave die may include a plurality of through-silicon vias; a plurality of first connection members on the first surface; and a plurality of second connection members electrically connecting the second surface and the third surface.

Embodiments of the inventive concepts provide a semiconductor structure which may include an interposer die including a first surface and a second surface opposite the first surface, the interposer die may include a plurality of first connection pads at the first surface, a plurality of second connection pads at the second surface, and a plurality of first through-silicon vias connected to the plurality of first connection pads and the plurality of second connection pads; a slave die including a third surface and a fourth surface opposite the third surface, the slave die may include a plurality of third connection pads at the third surface, and a plurality of second through-silicon vias on the plurality of third connection pads; a plurality of first connection members, where the first connection members among the plurality of first connection members are on a bottom surface of respective ones of first connection pads among the plurality of first connection pads; and a plurality of second connection members that electrically connect the second surface and the third surface.

Embodiments of the inventive concepts provide a semiconductor package which may include a substrate; an interposer die on the substrate and including a first surface and a second surface opposite the first surface, the interposer die may include a plurality of first connection pads at the first surface, a plurality of second connection pads at the second surface, and a plurality of first through-silicon vias connected to the plurality of first connection pads and the plurality of second connection pads; a slave die including a third surface and a fourth surface opposite the third surface, the slave die may include a plurality of third connection pads at the third surface, and a plurality of second through-silicon vias on the plurality of third connection pads; a plurality of first connection members, where the first connection members among the plurality of first connection members are on a bottom surface of respective ones of first connection pads among the plurality of first connection pads; a plurality of second connection members electrically connected to the second surface and the third surface; and a molding material molding the interposer die and the slave die on the substrate.

Embodiments of the inventive concepts provide a semiconductor package that forms an interposer designed to be capable of electrical connection to the slave die in consideration of constraints such as pitch, size, and design of the I/Os of the slave die, and may include a single chip where the slave die is disposed on the interposer or a multi-chip where a plurality of slave dies are disposed on the interposer.

Accordingly, when a defect occurs in a slave die manufactured for use in a 3D stacked semiconductor package, the slave die may be recycled without being discarded.

### BRIEF DESCRIPTION OF THE DRAWINGS

FIG. 1 is a cross-sectional view showing a semiconductor package including a slave die including third connection pads having a first pitch; an interconnection structure including second connection members having a first pitch and electrically connected to third connection pads; and an interposer die including second connection pads designed to be capable of electrical connection to the second connection members and first connection pads and first through-silicon vias having a second pitch.

FIG. 2 is an enlarged cross-sectional view showing first connection members; second connection members included in an interconnection structure; first connection pads, first through-silicon vias and second connection pads included in an interposer die; and third connection pads, second through-silicon vias, and fourth connection pads included in a slave die in FIG. 1.

FIG. 3 is a cross-sectional view showing a semiconductor package including a slave die including third connection pads having a first pitch; an interconnection structure electrically connected to third connection pads and including second connection members having a first pitch; and an interposer die including first connection pads designed to be capable of electrical connection to first connection members having a second pitch and first through-silicon vias and second connection pads having a first pitch.

FIG. 4 is an enlarged cross-sectional view showing first connection members; second connection members included in an interconnection structure; first connection pads, first through-silicon vias and second connection pads included in an interposer die; and third connection pads, second through-silicon vias, and fourth connection pads included in a slave die in FIG. 3.

FIG. 5 is a cross-sectional view showing a semiconductor package including a slave die including third connection pads having a first pitch; an interconnection structure electrically connected to third connection pads, bonded by hybrid bonding, and including first bonding pads and second bonding pads having a first pitch; and an interposer die including second connection pads designed to be capable of electrical connection to the first bonding pads and first connection pads and first through-silicon vias having a second pitch.

FIG. 6 is an enlarged cross-sectional view showing first connection members; first bonding pads, second bonding pads, first silicon insulation layer, and second silicon insulation layer included in an interconnection structure; first connection pads, first through-silicon vias, and second connection pads included in an interposer die; and third connection pads, second through-silicon vias, and fourth connection pads included in a slave die in FIG. 5.

FIG. 7 is a cross-sectional view showing a semiconductor package including a slave die including third connection pads of a first pitch; an interconnection structure electrically connected to the third connection pads, bonded by hybrid bonding, and including first bonding pads and second bonding pads having a first pitch; and an interposer die including first connection pads designed to be capable of electrical connection to first connection members having a second pitch and first through-silicon vias and second connection pads having a first pitch.

FIG. 8 is an enlarged cross-sectional view showing first connection members; first bonding pads, second bonding pads, a first silicon insulation layer, and a second silicon insulation layer included in an interconnection structure; first connection pads, first through-silicon vias, and second connection pads included in an interposer die; and third connection pads, second through-silicon vias, and fourth connection pads included in a slave die in FIG. 7.

FIG. 9 is a cross-sectional view showing a semiconductor package in which a first insulation member is disposed between a substrate and an interposer die, and a second insulation member is disposed between an interposer die and a slave die.

FIG. 10 illustrates a cross-sectional view showing a semiconductor package in which a width of an interposer die is smaller than a width of a slave die in a horizontal direction.

FIG. 11 is a cross-sectional view showing a semiconductor package in which a first slave die is disposed on an interposer die, and a second slave die is disposed on a first slave die.

FIG. 12 is a cross-sectional view showing providing of a substrate, as one of steps in a method for manufacturing a semiconductor package. FIG. 12 to FIG. 14 and FIG. 16 to FIG. 17 are a cross-sectional view showing a method for manufacturing a semiconductor package of FIG. 1.

FIG. 13 is a cross-sectional view showing bonding an interposer die on a substrate, as one of steps in a method for manufacturing a semiconductor package.

FIG. 14 is a cross-sectional view showing bonding a slave die on an interposer die, as one of steps in a method for manufacturing a semiconductor package.

FIG. 15 is a cross-sectional view showing, subsequent to the step described with respect to FIG. 13, bonding a slave die on an interposer by hybrid bonding, as one of steps in a method for manufacturing a semiconductor package. A method for manufacturing a semiconductor package subsequent to FIG. 15 may be equally applied by a method for manufacturing a semiconductor package of FIG. 16 to FIG. 17.

FIG. 16 is a cross-sectional view showing, on a substrate base, molding an interposer die and a slave die by a molding material, as one of steps in a method for manufacturing a semiconductor package.

FIG. 17 is a cross-sectional view showing forming conductive pads, an insulation layer, and third connection members on a bottom surface of a substrate base, as one of steps in a method for manufacturing a semiconductor package.

### DETAILED DESCRIPTION

Embodiments of the inventive concepts will be described more fully hereinafter with reference to the accompanying drawings, in which like reference numerals designate like elements throughout the specification. In the drawings, the size and thickness of each element are arbitrarily illustrated for ease of description, and the present disclosure is not necessarily limited to those illustrated in the drawings.

Also, it should be understood that when an element such as a layer, film, region, area, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

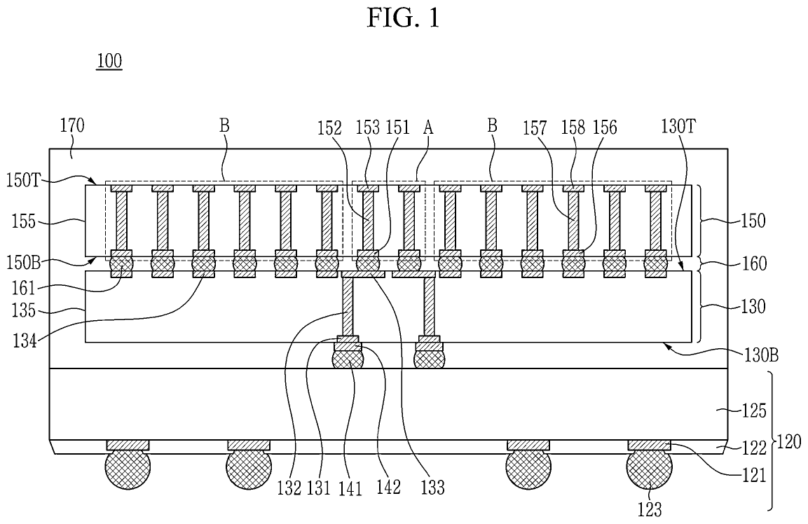

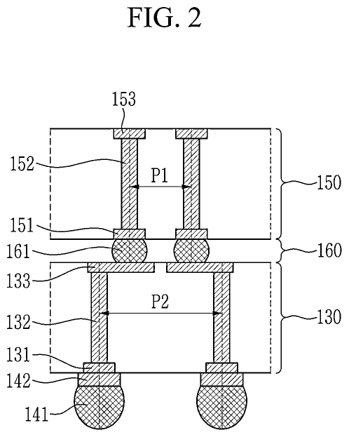

FIG. 1 is a cross-sectional view showing the semiconductor package 100 which may include a slave die 150 including third connection pads 151 having a first pitch P1 (see FIG. 2); an interconnection structure 160 including second connection members 161 having the first pitch P1 and electrically connected to the third connection pads 151; and an interposer die 130 including second connection pads 133 designed to be capable of electrical connection to the second connection members 161, and to first connection pads 131 and first through-silicon vias 132 having a second pitch P2 (see FIG. 2).

Referring to FIG. 1, the semiconductor package 100 may include a substrate 120, first connection members 141, the interposer die 130, the interconnection structure 160, the slave die 150 and a molding material 170.

The substrate 120 may include a substrate base 125, wiring patterns (not shown) and vias (not shown) within the substrate base 125, and first conductive pads 121, an insulation layer 122, and third connection members 123 on a bottom surface of the substrate base 125.

The substrate base 125 may interiorly include wiring patterns (not shown) and vias (not shown). The wiring patterns (not shown) and vias (not shown) within the substrate base 125 are designed for electrical compatibility with external devices. Therefore, compared to fine wiring patterns and fine vias formed in the slave die 150, normal wiring patterns (not shown) and normal vias (not shown) in the substrate base 125 have a large pitch and a large size, and it is difficult to directly electrically connect the substrate base 125 to the fine wiring patterns and fine vias of the slave die 150.

The first conductive pads 121 may be disposed below the bottom surface of the substrate base 125 and may be bonded to the third connection members 123. The first conductive pads 121 may electrically connect wiring patterns (not shown) and vias (not shown) within the substrate base 125 to the third connection members 123. In example embodiments, the first conductive pads 121 may include at least one of copper, aluminum, tungsten, nickel, gold, tin, titanium, and an alloy thereof.

The insulating layer 122 may be disposed below the bottom surface of the substrate base 125 and may isolate each of the third connection members 123. In example embodiments, the insulation layer 122 may be solder resist.

The third connection members 123 may electrically connect the first conductive pads 121 disposed below the bottom surface of the substrate base 125 to external devices. In example embodiments, the third connection members 123 may include at least one of tin, silver, lead, nickel, copper, and an alloy thereof.

The first connection members 141 may be disposed between the substrate 120 and second conductive pads 142, and electrically connect the second conductive pads 142 to the substrate 120. A pitch between neighboring first connection members 141 among the first connection members 141 may be smaller than a pitch between neighboring third connection members 123 among the third connection members 123. A size of a first connection member 141 may be smaller than a size of a third connection member 123. In example embodiments, the first connection members 141 may include at least one of tin, silver, lead, nickel, copper, and an alloy thereof.

The second conductive pads 142 may be disposed between the first connection members 141 and the first connection pads 131 of the interposer die 130, and electrically connect the first connection pads 131 to the first connection members 141. A pitch between neighboring second conductive pads 142 among the second conductive pads 142 may be smaller than a pitch between neighboring first conductive pads 121 among the first conductive pads 121. A size of a second conductive pad 142 may be smaller than a size of a first conductive pad 121. In example embodiments, the second conductive pads 142 may include at least one of copper, aluminum, tungsten, nickel, gold, tin, titanium, and an alloy thereof.

The interposer die 130 may be disposed between the substrate 120 and the slave die 150, for example between the second conductive pads 142 and the second connection members 161 of the interconnection structure 160. In example embodiments, the interposer die 130a may include a silicon interposer die.

The interposer die 130 may include an interposer base 135, and the first connection pads 131, the first through-silicon vias 132, the second connection pads 133 and a dummy pad 134 within the interposer base 135.

The interposer base 135 may be a wafer-level substrate made of silicon. The interposer base 135 may have a front-side 130B and a back-side 130T opposite the front-side 130B.

The first connection pads 131 may be disposed between the second conductive pads 142 and the first through-silicon vias 132, and electrically connect the first through-silicon vias 132 to the second conductive pads 142.

The first through-silicon vias 132 may be disposed between the first connection pads 131 and the second connection pads 133, and electrically connect the second connection pads 133 to the first connection pads 131. A first through-silicon via 132 may have one end in physical contact with a first connection pad 131 and the other end in physical contact with a second connection pad 133.

The second connection pads 133 may be disposed between the first through-silicon vias 132 and the second connection members 161 of the interconnection structure 160, and may extend in a horizontal direction to electrically connect the second connection members 161 of the interconnection structure 160 to the first through-silicon vias 132. Dummy pads 134 may be included and may correspond to pads for bonding to the second connection members 161 that are not bonded to the second connection pads 133 among the second connection members 161.

In example embodiments, the first through-silicon vias 132 may include at least one of tungsten, aluminum, copper and an alloy thereof. In example embodiments, the first connection pads 131, the second connection pads 133 and the dummy pads 134 may include at least one of copper, aluminum, silver, tin, gold, nickel, lead, titanium, and an alloy thereof, respectively.

The interconnection structure 160 may be disposed between the interposer die 130 and the slave die 150. The interconnection structure 160 may include the second connection members 161. A second connection member 161 may electrically connect a third connection pad 151 of the slave die 150 to the second connection pad 133 of the interposer die 130. In example embodiments, the second connection members 161 may include a micro-bump.

A 3D stacked semiconductor package including a plurality of chips stacked in a single package may include a master die, and one or more slave dies stacked on the master die. For example, a 3D stacked semiconductor package may be a high bandwidth memory (HBM).

The master die may be a buffer chip for controlling the one or more slave dies. For example, the master die may perform a logic operation on data output from the one or more slave dies and output a result of the logic operation to communicate with an external device. When manufacturing the 3D stacked semiconductor package, the master die may be disposed in lowermost portion among dies stacked on the 3D stacked semiconductor package for communication between the one or more slave dies and the external device, and may be directly connected to a substrate. That is, the master die may have a size of wiring patterns and a pitch of wiring patterns enabling electrical connection to the substrate. Therefore, when a defect occurs in the operation of the 3D stacked semiconductor package, such as the master die not meeting the specifications required for an individual chip, a master die may be conveniently and easily mounted on the substrate in the form of a single chip as a replacement for the defective mater die.

A slave die, such as slave die 150 for example, may be a memory cell chip having DRAM cells (not shown). The slave die may receive commands from the master die, and may communicate with the master die through through-silicon vias TSV and internal wirings of the slave die having fine pitch and fine size. For example, when manufacturing the 3D stacked semiconductor package, the one or more slave dies may be disposed on the master die. For example, the slave die may have wiring patterns having fine pitch and fine size that cannot be electrically connected to the substrate which has wiring patterns having relatively larger size and/or relatively larger pitch. Therefore, when a defect occurs in the operation of the 3D stacked semiconductor package, such as a slave die not meeting the specifications required for an individual chip, a slave die cannot be mounted on the substrate in the form of a single chip, and the defective slave dies are inevitably discarded and cannot be replaced.

Therefore, at least in order to solve the above problem, according to example embodiments of the inventive concepts, an interposer die is designed to be capable of electrical connection to a slave die in consideration of constraints such as pitch, size, and design of the input/output terminals or connectors (e.g., I/Os) of the slave die, and a replacement slave die may be electrically connected to the substrate of a 3D stacked semiconductor package for example by using the interposer die as an intermediate medium. For example, a semiconductor structure including the slave die as connected to the interposer die may be formed as a single chip.

In order for the slave die to be formed as a single chip, since the slave die must also function as a master die, the slave die may include a same configuration and circuitry as the master die. Accordingly, when the master die and the slave die are of the same type and/or of similar configuration, in the 3D stacked semiconductor package in which the one or more slave dies are disposed on the master die, at least one of circuits shared with the master die among the circuit blocks of the slave die, for example, logic circuits such as a delay synchronization circuit, a latency controller, reading FiFo, parallel-to-serial conversion unit, data input and output circuit, a command circuit, an address circuit, and a clock circuit are not used, and therefore are kept in on OFF-state. That is, in the 3D stacked semiconductor package, when the master die and the one or more slave dies are operated together, logic circuits controlling the master die and the one or more slave dies exist in the master die.

Therefore, when only a slave die is implemented as a single chip which may be used as a replacement slave die, according to example embodiments of the inventive concepts, logic circuits in the slave die of the single chip that correspond to logic circuits normally kept in the OFF-state in a slave die of a 3D stacked semiconductor package including a master die may instead be activated to an ON-state.

The slave die 150 may be disposed on the interposer die 130. In a region A, the slave die 150 may include a slave base 155, and the third connection pads 151, second through-silicon vias 152 and fourth connection pads 153 within the slave base 155. In order for the slave die 150 to operate as a single chip, the third connection pads 151, the second through-silicon vias 152, and the fourth connection pads 153 may serve to transmit signals and power.

The slave base 155 may be a wafer-level substrate made of silicon. The slave base 155 may have a front-side 150B and a back-side 150T opposite the front-side 150B. The slave base 155 may have an active surface on the front-side 150B.

The third connection pads 151 may be disposed between the second connection members 161 and the second through-silicon vias 152, and electrically connect the second through-silicon vias 152 to the second connection members 161.

The second through-silicon vias 152 may be disposed between the third connection pads 151 and the fourth connection pads 153, and electrically connect the fourth connection pads 153 to the third connection pads 151. A second through-silicon via 152 may have one end in physical contact with a third connection pad 151 and the other end in physical contact with a fourth connection pad 153.

The fourth connection pads 153 may be electrically connected to the second through-silicon vias 152. The third connection pads 151, the second through-silicon vias 152, and the fourth connection pads 153 may be electrically connected to internal circuits (not shown) formed in the slave die 150.

In a region B, the slave die 150 may include fifth connection pads 156, third through-silicon vias 157, and sixth connection pads 158.

The fifth connection pads 156 may be disposed between the second connection members 161 and the third through-silicon vias 157.

The third through-silicon vias 157 may be disposed between the fifth connection pads 156 and the sixth connection pads 158. A third through-silicon via 157 may have one end in physical contact with a fifth connection pad 156 and the other end in physical contact with a sixth connection pad 158.

The sixth connection pads 158 may be disposed on the third through-silicon vias 157.

A semiconductor structure of example embodiments of the inventive concepts is not stacked as a 3D stacked semiconductor package, but may instead be formed as a single chip including the slave die 150. In general, a semiconductor die disposed in an uppermost portion in the single chip or the multi-chip does not include the fifth connection pads 156, the third through-silicon vias 157, and the sixth connection pads 158 of FIG. 1. However, a purpose of a semiconductor package according to example embodiments of the inventive concepts is to recycle or replace a defective slave die which is manufactured to interconnect the slave dies that are stacked in a 3D stacked semiconductor package and that have defects. Accordingly, the slave die 150 in example embodiments of the inventive concepts may include the fifth connection pads 156, the third through-silicon vias 157 and the sixth connection pads 158. Therefore, the fifth connection pads 156 and the sixth connection pads 158 may be dummy pads, and the third through-silicon vias 157 may be dummy vias. Alternatively, the fifth connection pads 156, the sixth connection pads 158 and the third through-silicon vias 157 may serve as wirings to transmit only power without transmitting signals.

In example embodiments, the second through-silicon vias 152 and the third through-silicon vias 157 may include at least one of tungsten, aluminum, copper, and an alloy thereof. In example embodiments, the third connection pads 151, the fourth connection pads 153, the fifth connection pads 156 and the sixth connection pads 158 may include at least one of each copper, aluminum, silver, tin, gold, nickel, lead, titanium, and an alloy thereof.

The molding material 170 may be disposed on the substrate 120 and may mold and encapsulate the first connection members 141, the interposer die 130, the interconnection structure 160, and the slave die 150.

FIG. 2 is an enlarged cross-sectional view showing the first connection members 141; the second connection members 161 included in the interconnection structure 160; the first connection pads 131, the first through-silicon vias 132, and the second connection pads 133 included in the interposer die 130; and the third connection pads 151, the second through-silicon vias 152 and the fourth connection pads 153 included in the slave die 150, in FIG. 1.

Referring to FIG. 2, in line with the third connection pads 151, the second through-silicon vias 152 and the fourth connection pads 153 are disposed with the first pitch P1 of the slave die 150, and the second connection members 161 electrically connecting the slave die 150 to the interposer die 130 may be disposed to have the first pitch P1.

In addition, in line with the first connection members 141 electrically connected to the substrate 120, the first through-silicon vias 132 and the second connection pads 133 within the interposer die 130 may be disposed to have the second pitch P2.

In order to electrically connect the slave die 150 and the interposer die 130, because of an offset difference of the first pitch P1 and the second pitch P2, the interposer die 130 may include the second connection pads 133. So that bottom surfaces of the second connection pads 133 may be in contact with the first through-silicon vias 132 and upper surfaces of the second connection pads 133 may be in contact with the second connection members 161, the second connection pads 133 may extend in the horizontal direction.

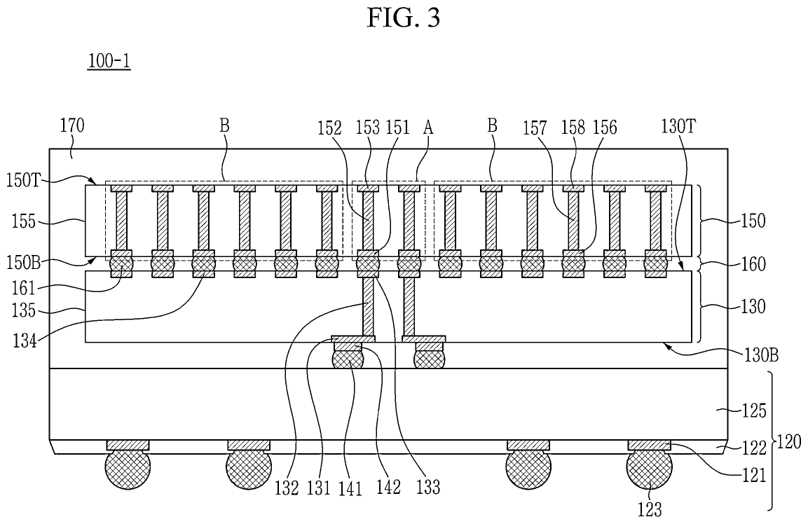

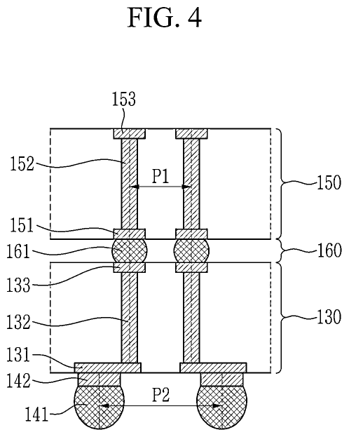

FIG. 3 illustrates a cross-sectional view showing a semiconductor package 100-1 which may include the slave die 150 including the third connection pads 151 having the first pitch P1 (see FIG. 4); the interconnection structure 160 electrically connected to the third connection pads 151 and including the second connection members 161 having the first pitch P1; and the interposer die 130 including the first connection pads 131 designed to be capable of electrical connection to the first connection members 141 having the second pitch P2 and the first through-silicon vias 132 and the second connection pads 133 having the first pitch P1.

Unlike the second connection pads 133 in FIG. 1 which are extended in the horizontal direction such that each second connection member among the second connection members 161 having the first pitch P1 is respectively electrically connected to a first through-silicon via among the first through-silicon vias 132 having the second pitch P2, the first connection pads 131 in FIG. 3 may be extended in the horizontal direction such that each first through-silicon via among the first through-silicon vias 132 may be respectively electrically connected to a conductive pad among the second conductive pads 142.

Features and configurations in FIG. 3 other than the interposer die 130 including the first through-silicon vias 132 and the second connection pads 133 having the first pitch P1 and the first connection pads 131 having the second pitch P2 and designed to be capable of electrical connection are the same as described with respect to FIG. 1. Therefore, features and configurations in FIG. 3 other than the interposer die 130 including the first through-silicon vias 132 and the second connection pads 133 having the first pitch P1 and the first connection pads 131 having the second pitch P2 and designed to be capable of electrical connection may be equally applied with the contents described with respect to FIG. 1.

FIG. 4 is an enlarged cross-sectional view showing the first connection members 141; the second connection members 161 included in the interconnection structure 160; the first connection pads 131, the first through-silicon vias 132, and the second connection pads 133 included in the interposer die 130; and the third connection pads 151, the second through-silicon vias 152, and the fourth connection pads 153 included in the slave die 150, in FIG. 3.

Referring to FIG. 4, in line with the third connection pads 151, the second through-silicon vias 152 and the fourth connection pads 153 of the slave die 150 are disposed with the first pitch P1, and the first through-silicon vias 132 and the second connection pads 133 of the interposer die 130 are disposed with the first pitch P1, and the second connection members 161 electrically connecting the slave die 150 to the interposer die 130 may be disposed to have the first pitch P1.

In addition, the first connection members 141 electrically connected to the substrate 120 may be disposed to have the second pitch P2.

In order to electrically connect the interposer die 130 to the substrate 120, because of the offset difference of the first pitch P1 and the second pitch P2, the interposer die 130 may include the first connection pads 131. So that bottom surfaces of the first connection pads 131 are in contact with the second conductive pads 142 and upper surfaces of the first connection pads 131 are in contact with the first through-silicon vias 132, the first connection pads 131 may be extended in the horizontal direction.

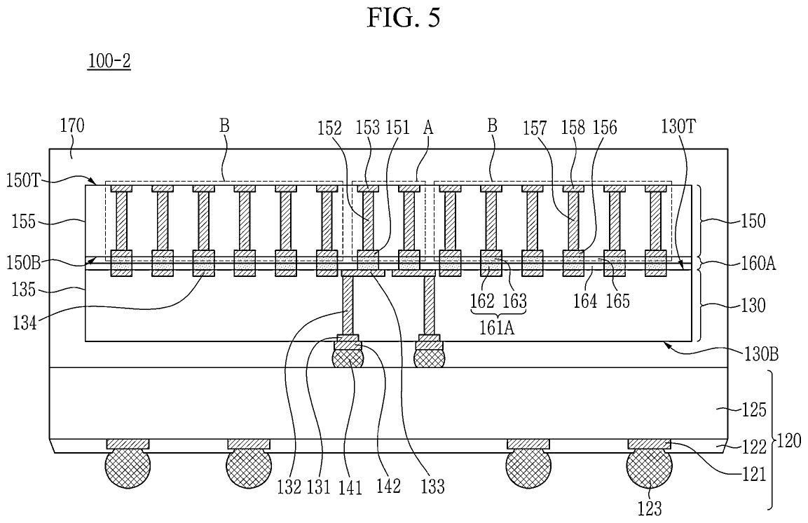

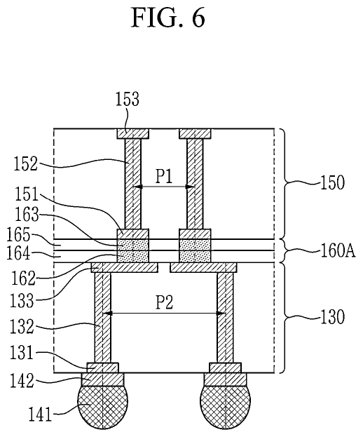

FIG. 5 is a cross-sectional view showing a semiconductor package 100-2 which may include the slave die 150 including the third connection pads 151 having the first pitch P1 (see FIG. 6); the interconnection structure 160A electrically connected to the third connection pads 151 and bonded by hybrid bonding, and including first bonding pads 162 and second bonding pads 163 having the first pitch P1; and the interposer die 130 including the second connection pads 133 designed to be capable of electrical connection to the first bonding pads 162 and the first connection pads 131, and the first through-silicon vias 132 having the second pitch P2 (see FIG. 6).

Referring to FIG. 5, the interposer die 130 and the slave die 150 may be bonded by hybrid bonding. Hybrid bonding may be understood for example as bonding two devices by fusing the same materials of the two devices using the bonding properties of the same material. The term hybrid may for example be understood to mean that two different types of bonding are made, for example, two devices are bonded by a first type of metal-metal bonding and a second type of non-metal-non-metal bonding. Hybrid bonding makes it possible to form I/Os with fine pitch.

The interconnection structure 160A may include the first bonding pads 162 and a first silicon insulation layer 164 on a back-side (e.g., upper surface) 130T of the interposer die 130, and the second bonding pads 163 and a second silicon insulation layer 165 front-side surface 150B of the slave die 150. The first bonding pads 162 and the second bonding pads 163 correspond to second connection members 161A. The first bonding pad 162 is directly bonded to the second bonding pad 163 by metal-metal hybrid bonding, and the first silicon insulation layer 164 may be directly bonded to the second silicon insulation layer 165 by non-metal-non-metal hybrid bonding.

Features and configurations in FIG. 5 other than that the interposer die 130 and the slave die 150 are bonded by hybrid bonding are the same as described with respect to FIG. 1. Therefore, features and configurations in FIG. 5 other than that the interposer die 130 and the slave die 150 are bonded by hybrid bonding may be equally applied with the contents described with respect to FIG. 1.

FIG. 6 is an enlarged cross-sectional view showing the first connection members 141; the first bonding pads 162, the second bonding pads 163, the first silicon insulation layer 164, and the second silicon insulation layer 165 included in an interconnection structure 160A; the first connection pads 131, the first through-silicon vias 132, and the second connection pads 133 included in the interposer die 130; and the third connection pads 151, the second through-silicon vias 152 and the fourth connection pads 153 included in the slave die 150, in FIG. 5.

Referring to FIG. 6, in line with the third connection pads 151, the second through-silicon vias 152 and the fourth connection pads 153 of the slave die 150 are disposed with the first pitch P1, and the second connection members 161A including the first bonding pads 162 and the second bonding pads 163 electrically connecting the slave die 150 to the interposer die 130 may be disposed to have the first pitch P1.

In addition, in line with the first connection members 141 electrically connected to the substrate 120, the first connection pads 131 and the first through-silicon vias 132 in the interposer die 130 may be disposed to have the second pitch P2.

In order to electrically connect the slave die 150 and the interposer die 130, because of the offset difference of the first pitch P1 and the second pitch P2, the interposer die 130 may include the second connection pads 133. So that the bottom surfaces of the second connection pads 133 are in contact with the first through-silicon via 132 and the upper surfaces of the second connection pads 133 are in contact with the first bonding pads 162, the second connection pads 133 may be extended in the horizontal direction.

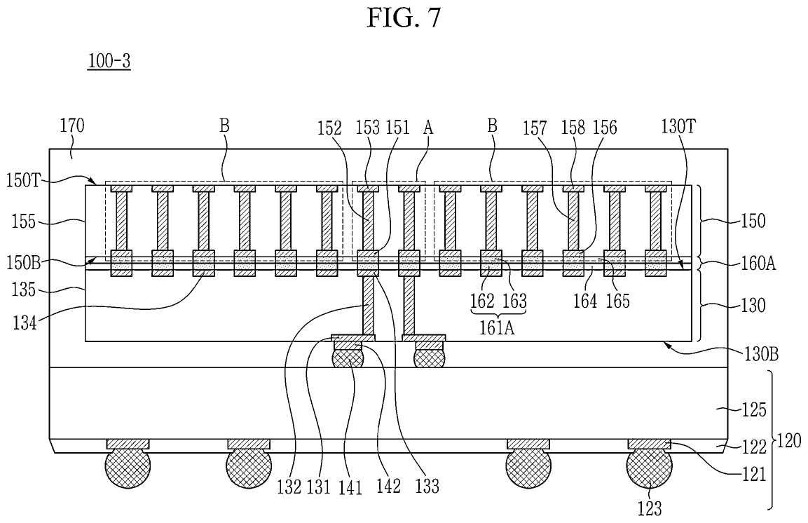

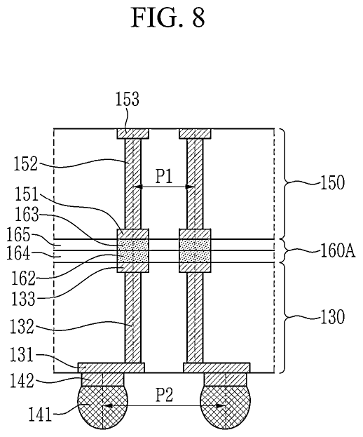

FIG. 7 is a cross-sectional view showing the semiconductor package 100-3 which may include the slave die 150 including the third connection pads 151 having the first pitch P1 (see FIG. 8); the interconnection structure 160A electrically connected to the third connection pads 151 and bonded by hybrid bonding, and including the first bonding pads 162 and the second bonding pads 163 having the first pitch P1; and the interposer die 130 including the first connection pads 131 designed to be capable of electrical connection to the first connection members 141 which have the second pitch P2 (see FIG. 8) and the first through-silicon vias 132, and the second connection pads 133, having the first pitch P1.

Unlike the second connection pads 133 in FIG. 5 which are extended in the horizontal direction such that each first bonding pad among the first bonding pads 162 having the first pitch P1 is respectively electrically connected to a first through-silicon via among the first through-silicon vias 132 having the second pitch P2, the first connection pads 131 may be extended in the horizontal direction in FIG. 7 such that each first through-silicon via among the first through-silicon vias 132 may be respectively electrically connected to a conductive pad among the second conductive pads 142.

Features and configurations in FIG. 7 other than the interposer die 130 including the first through-silicon vias 132 and the second connection pads 133 having the first pitch P1, and the first connection pads 131 having the second pitch P2 and designed to be capable of electrical connection to the first connection members 141 are the same as described with respect to FIG. 5. Therefore, features and configurations in FIG. 7 other than the interposer die 130 including the first through-silicon vias 132 and the second connection pads 133 having the first pitch P1 and the first connection pads 131 having the second pitch P2 and designed to be capable of electrical connection may be equally applied with the contents described with respect to FIG. 5.

FIG. 8 is an enlarged cross-sectional view showing the first connection members 141; the first bonding pads 162, the second bonding pads 163, the first silicon insulation layer 164, and the second silicon insulation layer 165 included in the interconnection structure 160A; the first connection pads 131, the first through-silicon vias 132, and the second connection pads 133 included in the interposer die 130; and the third connection pads 151, the second through-silicon vias 152 and the fourth connection pads 153 included in the slave die 150 in FIG. 7.

Referring to FIG. 8, in line with the third connection pads 151, the second through-silicon vias 152 and the fourth connection pads 153 of the slave die 150 are disposed with the first pitch P1, and the first through-silicon vias 132 and the second connection pads 133 of the interposer die 130 are disposed with the first pitch P1, and the first bonding pads 162 and the second bonding pads 163 electrically connecting the slave die 150 to the interposer die 130 may be disposed to have the first pitch P1.

In addition, the first connection members 141 electrically connected to the substrate 120 may be disposed to have the second pitch P2.

In order to electrically connect the interposer die 130 and the substrate 120, because of the offset difference of the first pitch P1 and the second pitch P2, the interposer die 130 may include the first connection pads 131. So that the bottom surfaces of the first connection pads 131 are in contact with the second conductive pads 142 and the upper surfaces of the first connection pads 131 are in contact with the first through-silicon vias 132, the first connection pads 131 may be extended in the horizontal direction.

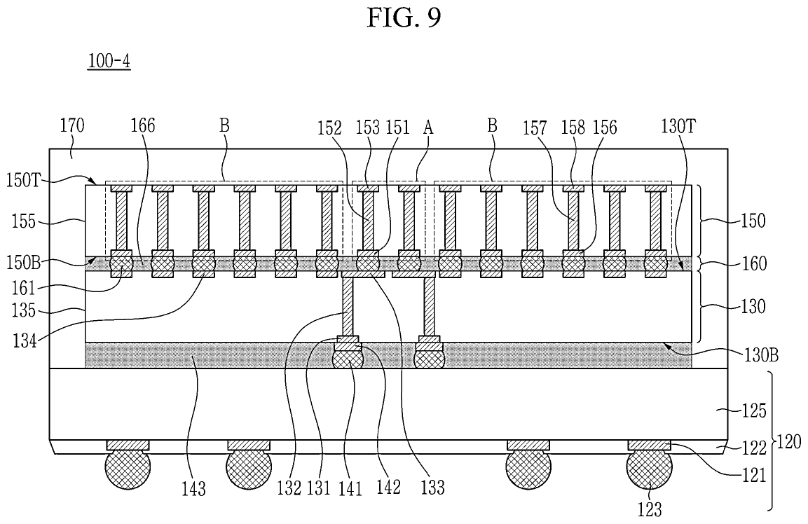

FIG. 9 is a cross-sectional view showing a semiconductor package 100-4 in which a first insulation member 143 is disposed between the substrate 120 and the interposer die 130, and a second insulation member 166 is disposed between the interposer die 130 and the slave die 150. Otherwise, the configuration of the semiconductor package 100-4 is similar to the configuration of the semiconductor package 100 of FIG. 1, and further description of such similar configuration is omitted for brevity.

Referring to FIG. 9, the first insulation member 143 may be disposed between the substrate 120 and the interposer die 130, and may surround and protect the first connection members 141. In example embodiments, the first insulation member 143 may include a molded under-fill (MUF). In example embodiments, the first insulation member 143 may include a non-conductive film (NCF).

The second insulation member 166 may be disposed between the interposer die 130 and the slave die 150, and may surround and protect the second connection members 161. In example embodiments, the second insulation member 166 may include a molded under-fill (MUF). In example embodiments, the second insulation member 166 may include a non-conductive film (NCF).

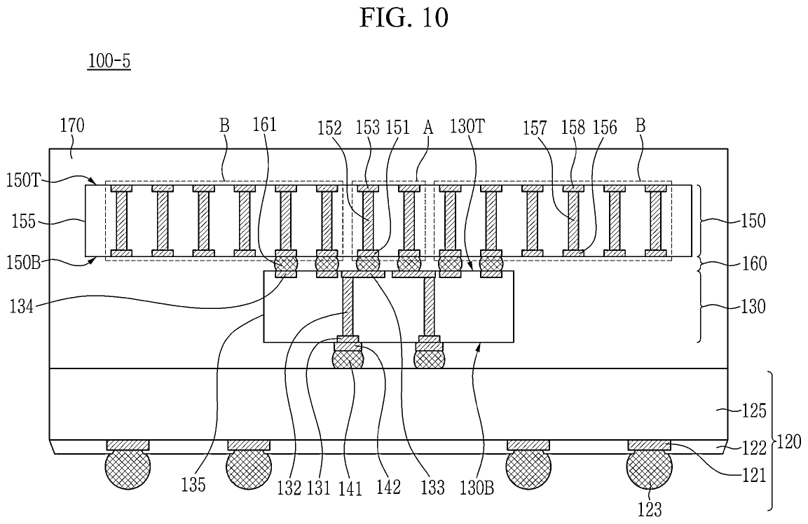

FIG. 10 is a cross-sectional view showing a semiconductor package 100-5 including the interposer die 130 having a width smaller than a width of the slave die 150 along the horizontal direction. Otherwise, the configuration of the semiconductor package 100-5 is similar to the configuration of the semiconductor package 100 of FIG. 1, and further description of such similar configuration is omitted for brevity.

Referring to FIG. 10, the width of the interposer die 130 may be smaller than the width of the slave die 150. In order for the slave die 150 to operate as a single chip, the third connection pads 151, the second through-silicon vias 152, and the fourth connection pads 153 disposed in the region A may serve to transmit signals and power. In contrast thereto, the fifth connection pads 156, the third through-silicon vias 157, and the sixth connection pads 158 disposed in the region B may respectively be dummy pads or dummy vias, or may serve as wirings to transmit only power without transmitting signals. Therefore, the interposer die 130 may have a small size enabling electrical connection to the third connection pads 151, the second through-silicon vias 152, and the fourth connection pads 153 disposed in the region A. A footprint of the interposer die 130 may be included within a footprint of the slave die 150. For example, a footprint of the interposer die 130 in top plan view is smaller than a footprint of slave die 150.

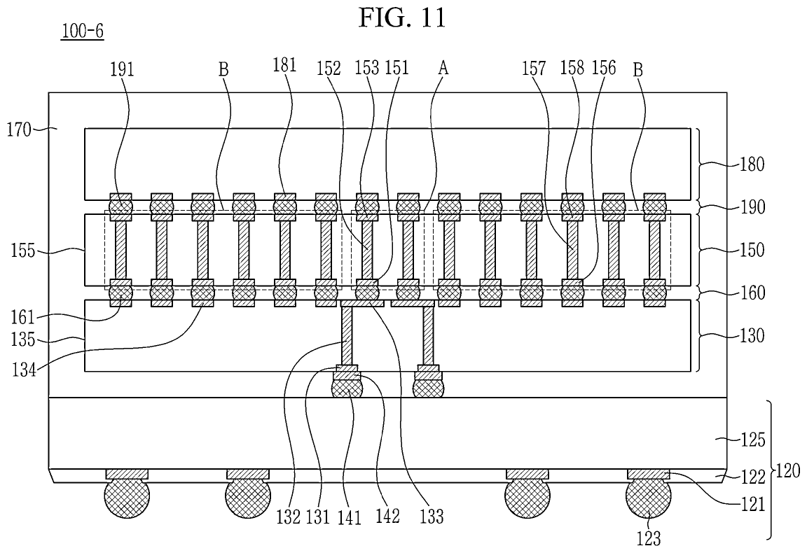

FIG. 11 is a cross-sectional view showing a semiconductor package 100-6 in which a first slave die 150 is disposed on the interposer die 130, and a second slave die (e.g., an additional slave die) 180 is disposed on the first slave die 150. Otherwise, the configuration of the semiconductor package 100-6 is similar to the configuration of the semiconductor package 100 of FIG. 1, and further description of such similar configuration is omitted for brevity.

Referring to FIG. 11, the first slave die 150 may be disposed on the interposer die 130, the second slave die 180 may be disposed on the first slave die 150. The first slave die 150 may serve as the master die, the second slave die 180 may serve as the slave die.

The second slave die 180 may include seventh connection pads 181, and may not include through-silicon vias. The second slave die 180 may be mounted on the first slave die 150 by an interconnection structure 190. The interconnection structure 190 may include fourth connection members 191. In example embodiments, the fourth connection members 191 may include a micro-bump. The fourth connection members 191 may be disposed between the fourth connection pads 153 and the seventh connection pads 181, and in addition between the sixth connection pads 158 and the seventh connection pads 181. Fourth connection members 191 may electrically connect the seventh connection pads 181 to the fourth connection pads 153 and the sixth connection pads 158.

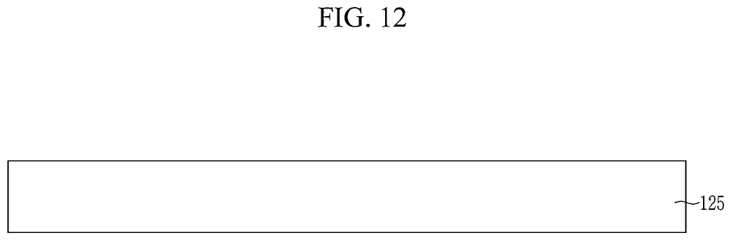

FIGS. 12-17 illustrate cross-sectional views explanatory of a method for manufacturing semiconductor packages according to example embodiments of the inventive concepts.

FIG. 12 is a cross-sectional view showing the substrate base 125 provided as part of the substrate 120, as processing in a method for manufacturing the semiconductor package 100. FIG. 12 to FIG. 14 and FIG. 16 to FIG. 17 are cross-sectional views showing a method for manufacturing the semiconductor package 100 of FIG. 1.

Referring to FIG. 12, the substrate base 125 among the substrate 120 is provided. In example embodiments, the substrate 120 may include any one of a rigid printed circuit board, a flexible printed circuit board, and a rigid-flexible printed circuit board. In example embodiments, the substrate 120 may include an embedded trace substrate (ETS). In example embodiments, the substrate 120 may include a single-layer printed circuit board and a multi-layer printed circuit board. In example embodiments, the substrate 120 may include other substrates that may undergo a molding process with an epoxy molding compound (EMC).

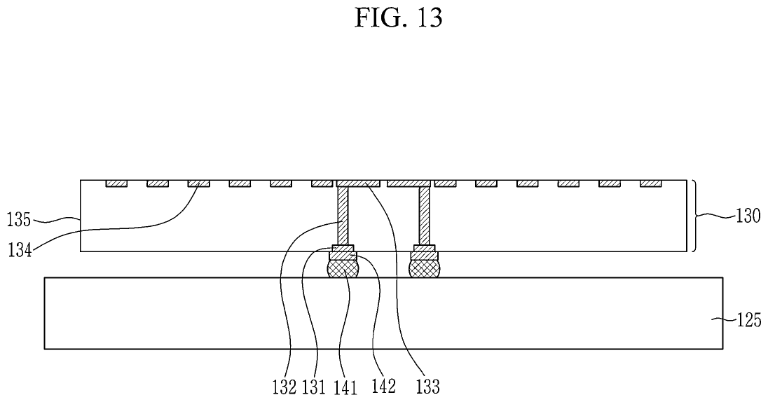

FIG. 13 is a cross-sectional view showing bonding of the interposer die 130 on the substrate 120, as processing in a method for manufacturing the semiconductor package 100.

The interposer die 130 is disposed on the substrate base 125 using the first connection members 141 by flip chip bonding. The interposer die 130 is disposed with its front-side facing the substrate base 125. In example embodiments, the first connection members 141 may include a micro-bump. In example embodiments, the first connection members 141 may include at least one of tin, silver, lead, nickel, copper, and an alloy thereof.

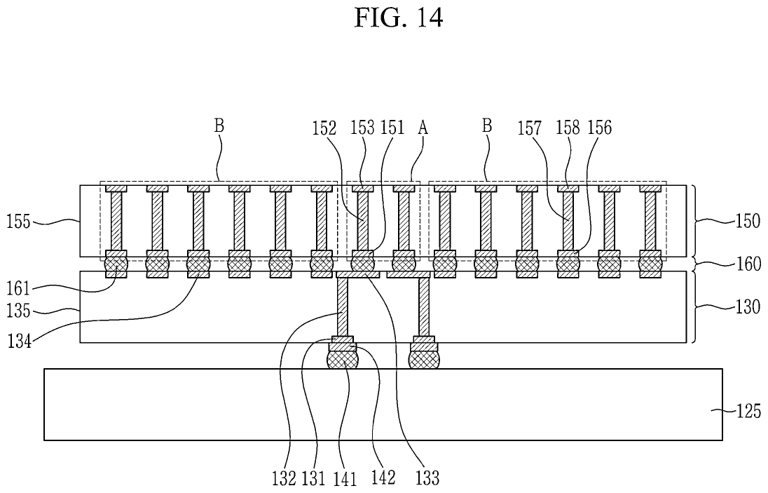

FIG. 14 is a cross-sectional view showing bonding of the slave die 150 on the interposer die 130, as processing in a method for manufacturing the semiconductor package 100.

The slave die 150 is disposed on the interposer die 130 using the second connection members 161 by flip chip bonding. The interposer die 130 is disposed with its active side facing the substrate base 125. In example embodiments, the second connection members 161 may include a micro-bump. In example embodiments, the second connection members 161 may include at least one of tin, silver, lead, nickel, copper, and an alloy thereof.

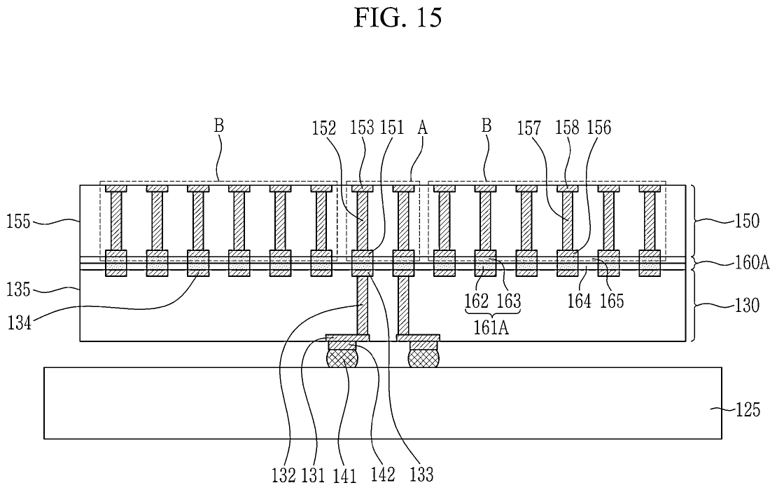

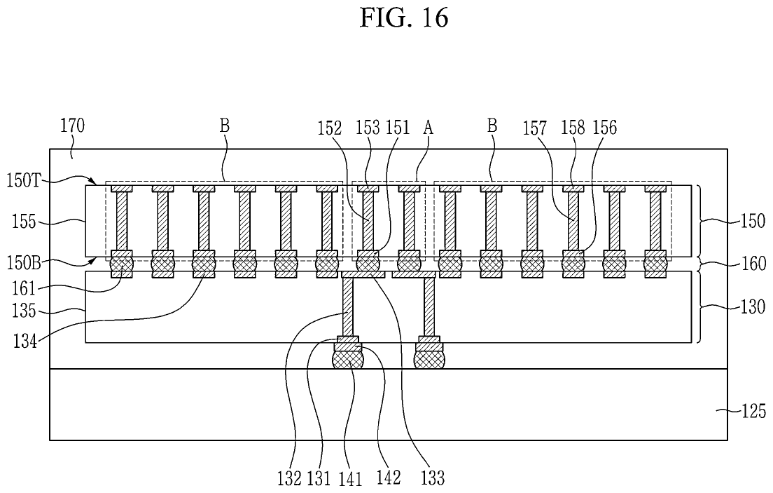

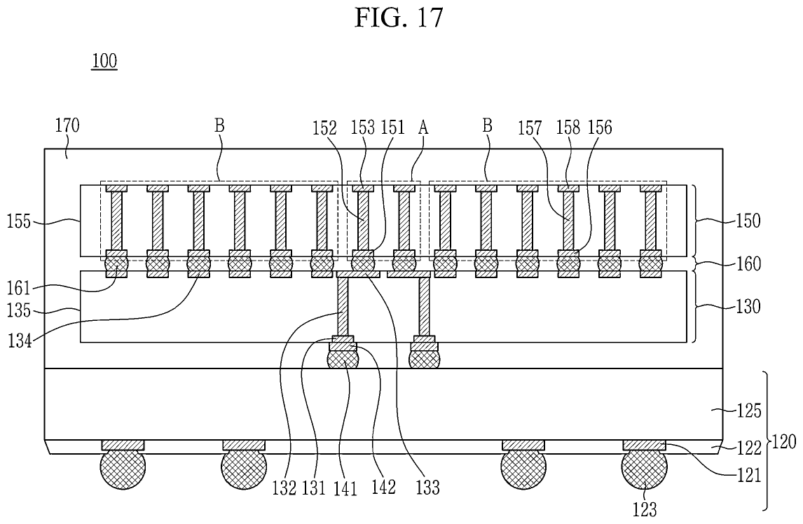

FIG. 15 is a cross-sectional view showing an alternative embodiment, subsequent to processing such as described with respect to FIG. 13, showing bonding of the slave die 150 on the interposer die 130 by hybrid bonding, as processing in a method for manufacturing a semiconductor package 100-3 such as shown in FIG. 7. It should be understood that additional processing for manufacturing a semiconductor package subsequently described with respect to FIGS. 16 and 17 may be applied to the semiconductor package 100-3 as well as the semiconductor package 100.

Referring to FIG. 15, the slave die 150 is bonded on the interposer die 130 by performing hybrid bonding. The slave die 150 is disposed with its active surface facing the interposer die 130. The first bonding pads 162 on an upper surface of the interposer die 130 and the second bonding pads 163 on a bottom surface of the slave die 150 may be directly bonded by metal-metal hybrid bonding. A metal bond is formed at an interface between the first bonding pads 162 on the upper surface of the interposer die 130 and the second bonding pads 163 on the lower surface of the slave die 150 by metal-metal hybrid bonding. In example embodiments of the inventive concepts, the first bonding pads 162 and the second bonding pads 163 may include copper. In example embodiments, the first bonding pads 162 and the second bonding pads 163 may be a metallic material to which the hybrid bonding may be applicable.

The first bonding pads 162 on the upper surface of the interposer die 130 and the second bonding pads 163 on the bottom surface of the slave die 150 may be configured as a same material, such that, after the hybrid bonding, an interface between the first bonding pads 162 on the upper surface of the interposer die 130 and the second bonding pads 163 on the bottom surface of the slave die 150 may disappear. The interposer die 130 and the slave die 150 may be electrically connected to each other, through the first bonding pads 162 on the upper surface of the interposer die 130 and the second bonding pads 163 on the bottom surface of the slave die 150.

The first silicon insulation layer 164 on the upper surface of the interposer die 130 and the second silicon insulation layer 165 on the bottom surface of the slave die 150 may be directly bonded by non-metal-non-metal hybrid bonding. A covalent bond is formed at an interface between the first silicon insulation layer 164 on the upper surface of the interposer die 130 and the second silicon insulation layer 165 on the bottom surface of the slave die 150 by non-metal-non-metal hybrid bonding.

In example embodiments, the first silicon insulation layer 164 and the second silicon insulation layer 165 may include silicon oxide or TEOS formation oxide. In example embodiments, the first silicon insulation layer 164 and the second silicon insulation layer 165 may include SiO2. In example embodiments, the first silicon insulation layer 164 and the second silicon insulation layer 165 may be silicon nitride, silicon oxynitride, or other suitable dielectric material. In example embodiments, the first silicon insulation layer 164 and the second silicon insulation layer 165 may include SiN or SiCN.

The first silicon insulation layer 164 on the upper surface of the interposer die 130 and the second silicon insulation layer 165 on the bottom surface of the slave die 150 may be configured as a same material, such that, after the hybrid bonding, an interface between the first silicon insulation layer 164 on the upper surface of the interposer die 130 and the second silicon insulation layer 165 on the bottom surface of the slave die 150 may disappear.

FIG. 16 is a cross-sectional view showing, on the substrate base 125, molding the interposer die 130 and the slave die 150 by the molding material 170, as further processing in a method for manufacturing the semiconductor package 100.

Referring to FIG. 16, on the substrate base 125, the interposer die 130 and the slave die 150 are molded by the molding material 170. In example embodiments, the process of molding with the molding material 170 may include a compression molding or transfer molding process. In example embodiments, the molding material 170 may be formed of a thermosetting resin such as epoxy resin. In example embodiments, the molding material 170 may be an epoxy molding compound (EMC).

FIG. 17 is a cross-sectional view showing forming conductive pads, an insulation layer, and first connection members on the bottom surface of the substrate base 125, as processing in a method for manufacturing the semiconductor package 100.

Referring to FIG. 17, the first conductive pads 121, the insulation layer 122 and the third connection members 123 are formed on the bottom surface of the substrate base 125. In example embodiments, the first conductive pads 121 may include at least one of copper, nickel, zinc, gold, silver, platinum, palladium, chromium, titanium, and an alloy thereof. In example embodiments, the insulation layer 122 may include solder resist. In example embodiments, the third connection member 123 may include at least one of tin, silver, lead, nickel, copper, or an alloy thereof. In example embodiments, the first conductive pad 121 may be formed by performing a sputtering process or an electrolytic plating process after forming a seed metal layer. In example embodiments, the insulation layer 122 may be formed by a CVD, ALD, or PECVD process.

While example embodiments of the inventive concepts have been described in connection with what is presently considered to be practical embodiments, it is to be understood that the inventive concepts should not be limited to the disclosed embodiments, but on the contrary should cover various modifications and equivalent arrangements included within the spirit and scope of the appended claims.

What is claimed is:

1. A semiconductor structure comprising:
an interposer die comprising a first surface and a second surface that is opposite the first surface;
a slave die comprising a third surface and a fourth surface that is opposite the third surface, wherein the slave die includes a plurality of through-silicon vias;
a plurality of first connection members on the first surface; and
a plurality of second connection members configured to electrically connect the second surface and the third surface.

2. The semiconductor structure of claim 1, wherein the first surface is a front-side of the interposer die, and the second surface is a back-side of the interposer die.

3. The semiconductor structure of claim 1, wherein the interposer die comprises a silicon interposer die.

4. The semiconductor structure of claim 1, wherein the slave die is configured to operate as a single chip.

5. The semiconductor structure of claim 1, further comprising a non-conductive film (NCF) between the interposer die and the slave die, and surrounding the plurality of second connection members.

6. The semiconductor structure of claim 1, wherein a footprint of the interposer die in top plan view is smaller than and included within a footprint of the slave die.

7. The semiconductor structure of claim 1, further comprising an additional slave die on the slave die.

8. A semiconductor structure, comprising:
an interposer die comprising a first surface and a second surface that is opposite the first surface, wherein the interposer die comprises
a plurality of first connection pads at the first surface,
a plurality of second connection pads at the second surface, and
a plurality of first through-silicon vias connected to the plurality of first connection pads and the plurality of second connection pads;
a slave die comprising a third surface and a fourth surface opposite the third surface, wherein the slave die comprises
a plurality of third connection pads at the third surface, and
a plurality of second through-silicon vias on the plurality of third connection pads;
a plurality of first connection members, wherein the first connection members among the plurality of first connection members are on a bottom surface of respective ones of first connection pads among the plurality of first connection pads; and
a plurality of second connection members configured to electrically connect the second surface and the third surface.

9. The semiconductor structure of claim 8, wherein neighboring second connection members among the plurality of second connection members, and neighboring third connection pads among the plurality of third connection pads have a first pitch,
neighboring first connection members among the plurality of first connection members, neighboring first connection pads among the plurality of first connection pads, and neighboring first through-silicon vias among the plurality of first through-silicon vias have a second pitch, and
the second pitch is larger than the first pitch.

10. The semiconductor structure of claim 9, wherein each second connection pad among the plurality of second connection pads extends in a horizontal direction,
a surface of each of the second connection pads is in contact with respective ones of first through-silicon vias among the plurality of first through-silicon vias, and
another surface of each of the second connection pads is in contact with respective ones of second connection members among the plurality of second connection members.

11. The semiconductor structure of claim 8, wherein neighboring first through-silicon vias among the plurality of first through-silicon vias, neighboring second connection pads among the plurality of second connection pads, neighboring second connection members among the plurality of second connection members, and neighboring third connection pads among the plurality of third connection pads have a first pitch,
neighboring first connection members among the plurality of first connection members have a second pitch, and
the second pitch is larger than the first pitch.

12. The semiconductor structure of claim 11, wherein each first connection pad among the plurality of first connection pads extends in a horizontal direction,
a surface of each of the first connection pads is in contact with respective ones of first through-silicon vias among the plurality of first through-silicon vias, and
another surface of each of the first connection pads is in contact with respective ones of first connection members among the plurality of first connection members.

13. The semiconductor structure of claim 8, wherein the slave die further comprises a plurality of third through-silicon vias.

14. The semiconductor structure of claim 13, wherein the plurality of third through-silicon vias comprise dummy vias.

15. The semiconductor structure of claim 13, wherein the plurality of third through-silicon vias transfer only power.

16. The semiconductor structure of claim 8, wherein the plurality of second connection members comprise a micro-bump.

17. The semiconductor structure of claim 8, wherein each second connection member among the plurality of second connection members comprises a first bonding pad and a second bonding pad on the first bonding pad,
wherein the first bonding pad and the second bonding pad are directly bonded.

18. The semiconductor structure of claim 17, further comprising:
a first silicon insulation layer surrounding side surfaces of the first bonding pad; and
a second silicon insulation layer surrounding side surfaces of the second bonding pad and on the first silicon insulation layer,
wherein the first silicon insulation layer and the second silicon insulation layer are directly bonded.

19. A semiconductor package, comprising:
a substrate;
an interposer die on the substrate and comprising a first surface and a second surface opposite the first surface, wherein the interposer die comprises
a plurality of first connection pads at the first surface,
a plurality of second connection pads at the second surface, and
a plurality of first through-silicon vias connected to the plurality of first connection pads and the plurality of second connection pads;
a slave die comprising a third surface and a fourth surface opposite the third surface, wherein the slave die comprises
a plurality of third connection pads at the third surface, and
a plurality of second through-silicon vias on the plurality of third connection pads;
a plurality of first connection members, wherein the first connection members among the plurality of first connection members are on a bottom surface of respective ones of first connection pads among the plurality of first connection pads;
a plurality of second connection members configured to electrically connect the second surface and the third surface; and
a molding material molding the interposer die and the slave die on the substrate.

20. The semiconductor package of claim 19, further comprising a non-conductive film (NCF) between the substrate and the interposer die, and surrounding the plurality of first connection members.
